(19) United States
(12) Patent Application Publication
(10) Pub. No.: US 2020/0163237 A1
(43) Pub. Date: May 21, 2020

(54) ENCLOSURE FOR SECURITY SYSTEM

(71) Applicant: Opendoor Labs Inc., San Francisco, CA (US)

(72) Inventors: Gabrielle Kozlowski, Sausalito, CA (US); Bradford Ludwig Bonney, San Francisco, CA (US); Daniel Neighman, Walnut Creek, CA (US)

(21) Appl. No.: 16/687,769

(22) Filed: Nov. 19, 2019

Related U.S. Application Data
(60) Provisional application No. 62/769,128, filed on Nov. 19, 2018.

(51) Int. Cl. H05K 5/02; H05K 5/00; H02G 3/08; H02G 3/03; H02G 3/12; H02G 3/14; G08B 3/10

(52) U.S. Cl. CPC H05K 5/0213; H05K 5/0008; H05K 5/0247; H05K 5/0204; H05K 5/0243; H02G 3/03; H02G 3/12; H02G 3/14; G08B 3/10; H02G 3/083

(57) ABSTRACT

An enclosure for a security system includes a substantially planar rear plate having a wall with a first and second aperture. Both apertures extend through the rear plate. The first aperture is shaped and sized to match a wall socket, and the second aperture is sized to receive a fastener. The second aperture is disposed above or below the first aperture and positioned to line up with a fastener hole in the wall socket. The rear plate sits substantially flush against a wall coupled to the wall socket. A front housing is coupled to the rear plate forming an enclosed volume adequate to house a plurality of electronic components.

### CLAIM OF PRIORITY

The present application is a non-provisional of, and claims the benefit of U.S. Provisional Patent Application No. 62/769,128 (Attorney Docket No. 4815.012PRV) filed Nov. 19, 2018; the entire contents of which are incorporated herein by reference.

### BACKGROUND

Enclosures or housings come in many shapes, sizes and forms. They are typically used to provide a substrate on which internal components may be supported as well as providing protection against the environment or external forces. They must provide adequate ventilation or cooling if applicable. Additionally, housings or enclosures must be sized and shaped to fit in the working space, and often include features to provide a pleasing ornamental design.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various examples discussed in the present document.

FIG. 1A illustrates a perspective view of an example of an enclosure.

FIG. 1B illustrates a perspective view of the enclosure of FIG. 1A.

FIG. 2 illustrates a perspective view of a front housing of the enclosure in FIG. 1A.

FIG. 3 illustrates a perspective view of a rear plate of the enclosure in FIG. 1A.

FIG. 4 illustrates an example of the rear plate in FIG. 3 coupled to a wall.

### DETAILED DESCRIPTION

Home or other industrial electronic systems often require a housing to contain electronic components that fit into the limited working space, as well as provide an esthetically pleasing design. Additionally, in certain situations it may be desirable that the housing have a low profile so that it does not get bumped by people or equipment passing by and provides adequate ventilation and cooling to the electronic components disposed in the housing. Moreover, the electronic components may require electrical power and therefore it would be desirable if the housing provides easy access to adjacent power outlets. The housing should be easy to install and also be difficult to open in order to minimize the possibility of tampering with the electronic components. At least some of these objectives will be satisfied by the examples disclosed herein.

Examples of an enclosure or housing are used in a home security system. This is not intended to be limiting and one of skill in the art will appreciate that the examples disclosed herein may be used in any number of other applications.

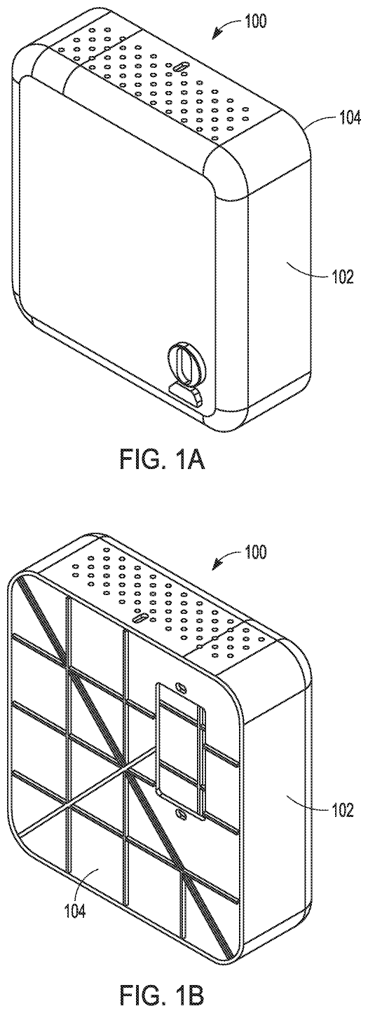

FIG. 1A illustrates a perspective view of an enclosure 100 looking at the front external surface of the enclosure. In this example, the enclosure is for holding electronic components which may be part of a home security system or other home electronic systems. The enclosure 100 includes a rear plate 104 and a front housing 102 which are described in greater detail below.

FIG. 1B illustrates a perspective view of the enclosure 100 shown in FIG. 1A looking at the rear external surface. The enclosure includes the front housing 102 and the rear plate 104.

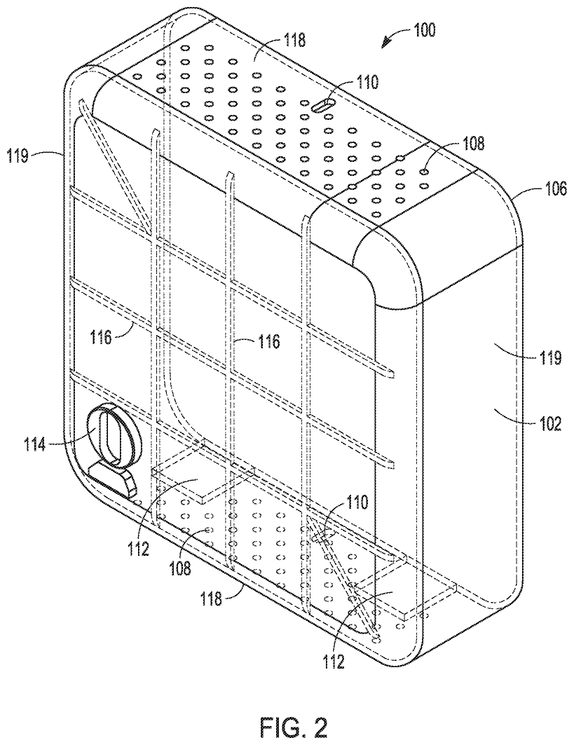

FIG. 2 illustrates a perspective view of the front housing 102 used in enclosure 100, looking at the external surface of the front housing. The front housing 102 includes an upper and lower wall 118 that may be flat and planar and parallel with one another. Two side walls 119 may also be flat and planar and parallel with one another and join the two upper and lower walls 118 together to form the side wall perimeter. Radiused corners 106 may be disposed between the upper and lower walls and the adjacent side wall to avoid sharp edges and provide a more esthetically pleasing design. The radiused corners 106 may also provide stress concentration reliefs. Optionally the upper and/or lower walls 118 may include a plurality of apertures 108 disposed through the upper and lower walls 118. These apertures may be used to allow air flow therethrough to provide adequate cooling or ventilation to the enclosure. In particular when the enclosure houses electronic components, heat is generated and therefore cooling, or ventilation may be required to prevent overheating. The apertures may be on the upper wall only, on the lower wall only, or on both the upper and lower walls 118. The apertures may be any shape such as round holes, oval holes, square holes, elliptical holes, triangular holes, and so forth. Additionally, any hole pattern may be used. In this example, the hole pattern includes a two-dimensional array of holes including a plurality of rows of holes with each row having holes disposed linearly along each row. Holes in adjacent rows may be aligned with one another or staggered. FIG. 2 shows the holes 108 in staggered rows. Other hole patterns may be employed such as random patterns, non-linear arrays, and so forth.

The upper wall 118 may also include an aperture 110 extending through the upper wall. The aperture 110 may be sized and shaped to receive a fastener such as a screw or pin in order to couple the front housing 102 with the rear plate 104 that will be discussed below. The lower wall 118 may have a similar aperture 110 extending through the wall to receive a second fastener such as a pin or screw. The aperture 110 may be a round hole for receiving the fastener, or it may be an oval shaped slot in order to allow some adjustment of front housing position when the fastener is disposed therein. A slotted oval hole permits the rear plate to move relative to the front housing when the fastener is loose, and position may be fixed once the fastener is tightened.

The lower wall 118 may optionally include one or two or more cutouts 112 which are sized and shaped to fit a cable connector. In this example, the cutouts 112 are configured to receive an Ethernet cable connector.

An optional ornamental design such as a logo 114 may be disposed on the front external face of the front housing, or on a front internal face of the housing, and either may be on the left side or the right side, or anywhere on the housing. FIG. 2 shows the ornamental design on an external surface of the front housing. The rest of the front face may be flat and planar and not have any other apertures passing therethrough. The outer surface may be textured for aesthetic reasons if desired.

The front housing 102 may also include a plurality of ribs or gussets 116 on an inside surface of the front housing so they are not visible once the front housing is joined with the rear plate. The ribs may be in any number of shapes or patterns and provide structural strength to the front housing. Here the ribs 116 are disposed horizontally and vertically to form a grid of ribs. Some ribs 116 are diagonal. One of skill in the art will appreciate that this is not intended to be limiting and any number of rib patterns are possible.

The side walls 119 may include any of these features but in this example the side walls 119 are flat, planar surfaces without any apertures extending therethrough.

The front housing 102 may be injection molded from any number of polymers or it may be formed using any number of materials and techniques known in the art.

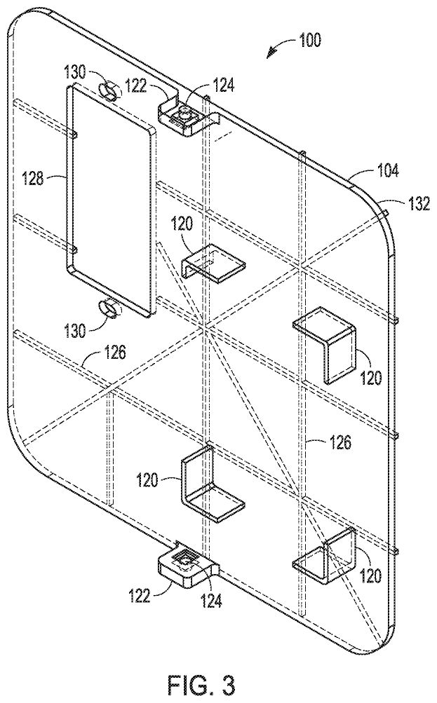

FIG. 3 illustrates a perspective view of the rear plate 104 of the enclosure 100 looking at the internal surface. The rear plate 104 may be substantially flat and planar and thin to provide a low profile. This allows the rear plate to sit substantially flush against the wall when mounted thereto.

The rear plate 104 may include rounded or radiused corners 132 to match those of the front housing 102. Optional standoffs 120 may be disposed on the inner surface and in this example are L-shaped and extend upward and away from the rear plate surface. Four standoffs 120 form a rectangular region which is sized and shaped to receive any component, such as a processor board. The standoffs allow the processor board or other component to be secured to the rear plate.

The rear plate 104 optionally may also include an upper and lower tabs 122 which extend upward and away from the rear plate. The upper and lower tabs 122 include an aperture 124 extending therethrough. The aperture may be threaded to receive a fastener that is passed through the apertures 110 in the front housing (best seen in FIG. 2), thereby allowing the front housing 102 to be coupled with the rear plate 104.

The rear plate 104 also includes an aperture 128 that extends through the rear plate 104. The aperture 128 is sized and shaped so that when the rear plate 104 is disposed against a wall socket, the wall socket will be accessible from the aperture 128. The aperture 128 may be any shape but in this example, it is rectangularly shaped and slightly oversized relative to the wall socket. Apertures 130 may be above and below the rectangular aperture. The apertures 130 are also sized and shaped to receive a fastener such as a screw so that the rear plate 104 may be threadably or otherwise engaged with the wall socket thereby securing the rear plate 104 to the wall in a substantially flush manner. The apertures 130 may be circular or slotted to allow minor adjustments of the rear plate during the fitting with the wall socket. Apertures 130 are positioned to align with standard holes in a wall socket power outlet box (without the wall socket cover plate).

The rear plate 104 may also include ribs 126 which may be in any pattern to provide additional structure and support to the rear plate. Here the ribs 126 include a plurality of horizontal ribs, vertical ribs and diagonal ribs. The rear plate 104 may be injection molded from any number of known polymers or manufactured using other materials and techniques known in the art.

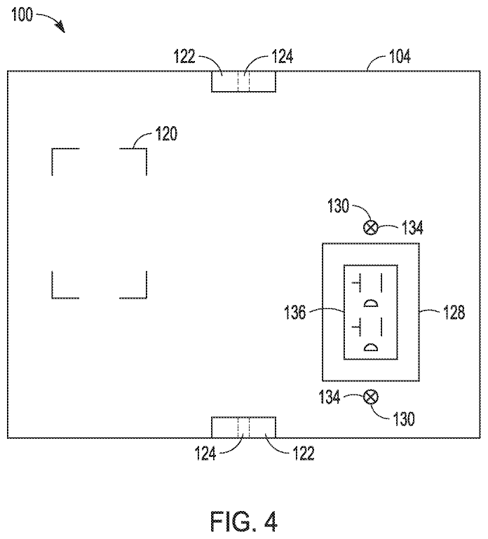

Once the rear plate 104 is mounted to the wall socket and disposed against a wall, the aperture 128 allows access to the wall socket and therefore power cords may be plugged into the wall socket so that the electronics in the enclosure 100 can received power. FIG. 4 illustrates the rear plate 104 of enclosure 100 mounted to the wall socket 136 with fasteners such as screws 134 passing through both upper and lower apertures 130. The front housing is removed for ease in viewing. The receptacle formed by standoffs 120 forms a rectangular region where a processor board (not illustrated) may be mounted or other components maybe disposed therein. Other electronic components may be disposed on the rear plate 104 or in the volume created between the rear plate 104 and the front housing 102 including an audible alarm element, a memory card, a modem, a power cord, and so forth. The electronic system in the enclosure may be wirelessly or otherwise coupled to a motion sensor, smartlock, or any other device or component located elsewhere in a house. Thus, the enclosure forms part of a home security and monitoring system.

### NOTES AND EXAMPLES

The following, non-limiting examples, detail certain aspects of the present subject matter to solve the challenges and provide the benefits discussed herein, among others.

Example 1 is an enclosure for a security system comprises a substantially planar rear plate, the rear plate having a wall with a first aperture, and a second aperture, both apertures extending through the rear plate, the first aperture shaped and sized to match a wall socket, and wherein the second aperture is sized to receive a fastener, wherein the second aperture is disposed above or below the first aperture and positioned to line up with a fastener hole in the wall socket, and wherein the rear plate sits substantially flush against a wall when disposed against the wall and coupled to the wall socket, and a front housing coupled to the rear plate forming an enclosed volume adequate to house a plurality of electronic components.

Example 2 is the enclosure of Example 1, wherein the first aperture is rectangularly shaped.

Example 3 is the enclosure of any of Examples 1-2, further comprising a third aperture extending through the rear plate, the third aperture sized to receive a fastener.

Example 4 is the enclosure of any of Examples 1-3, wherein the front housing is releasably coupled to the rear plate.

Example 5 is the enclosure of any of Examples 1-4, wherein the front housing is fixedly coupled to the rear plate.

Example 6 is the enclosure of any of Examples 1-5, wherein the rear plate or the front housing is substantially square or rectangularly shaped.

Example 7 is the enclosure of any of Examples 1-6, wherein the rear plate further comprises a plurality of standoffs extending therefrom, the plurality of standoffs forming a region for receiving and holding at least some of the plurality of electronic components.

Example 8 is the enclosure of any of Examples 1-7, further comprising one or more tabs extending outward and away from the rear plate, the one or more tabs having an aperture extending therethrough that cooperates with an aperture on the front housing, the aperture in the one or more tabs sized to receive a fastener.

Example 9 is the enclosure of any of Examples 1-8, wherein the front housing comprises a side wall with the aperture on the front housing extending therethrough and aligned with the aperture on the one or more tabs, and wherein the aperture on the front housing is sized to receive the fastener.

Example 10 is the enclosure of any of Examples 1-9, further comprising one or more apertures extending through a side wall of the front housing, the one or more apertures sized and shaped to receive an Ethernet cable connector.

Example 11 is the enclosure of any of Examples 1-10, further comprising a plurality of ventilation apertures passing through a sidewall of the front housing.

Example 12 is a security system comprising a security system, said system comprising a substantially planar rear plate, the rear plate having a wall with a first aperture and a second aperture extending therethrough, the first aperture shaped and sized to match a wall socket, and wherein the second aperture is sized to receive a fastener, and wherein the second aperture is disposed above or below the first aperture and positioned to line up with a fastener hole in the wall socket, and wherein the rear plate sits substantially flush against a wall when disposed against the wall and coupled to the wall socket; a front housing coupled to the rear plate forming an enclosed volume adequate to house a plurality of electronic components; and the plurality of electronic components disposed in the enclosed volume.

Example 13 is the system of Example 12, wherein the plurality of electronic components comprise a processor, an audible alarm, a memory card, or a modem.

Example 14 is the system of any of Examples 12-13, further comprising one or more motion sensors or a smartlock wirelessly coupled with the plurality of electronics.

Example 15 is a method for mounting an enclosure for a security system to a wall, said method comprising providing an enclosure for a security system, the enclosure comprising a substantially planar rear plate and a front housing; positioning the rear plate against the wall; aligning an aperture in the rear plate with a wall socket such that the wall socket is accessible through the aperture; coupling the rear plate to the wall socket with a fastener, wherein the rear plate rests substantially flush against the wall; coupling one or more electronic components to the rear plate; and attaching the front housing to the rear plate to form an enclosed volume that houses the one or more electronic components.

Example 16 is the method of Example 15, wherein the one or more electronic components comprise a power plug, the method further comprising passing the power plug through the aperture in the rear plate and plugging the power plug into the wall socket.

Example 17 is the method of any of Examples 15-16, wherein coupling the rear plate to the wall socket comprises aligning an aperture in the rear plate with an aperture in the wall socket; passing a fastener through an aperture in the rear plate and into the aperture in the wall socket; and threadably engaging the fastener with the wall socket.

Example 18 is the method of any of Examples 15-17, wherein attaching the front housing to the rear plate comprises releasably attaching the front housing to the rear plate.

Example 19 is the method of any of Examples 15-18, wherein attaching the front housing to the rear plate comprises fixedly attaching the front housing to the rear plate.

Example 20 is the method of any of Examples 15-19, wherein attaching the front housing to the rear plate comprises passing a fastener through an aperture in the front housing and engaging the fastener with an aperture disposed in a tab extending outward and away from the rear plate.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An enclosure for a security system, said enclosure comprising:
a substantially planar rear plate, the rear plate having a wall with a first aperture, and a second aperture, both apertures extending through the rear plate, the first aperture shaped and sized to match a wall socket, and wherein the second aperture is sized to receive a fastener,
wherein the second aperture is disposed above or below the first aperture and positioned to line up with a fastener hole in the wall socket, and
wherein the rear plate sits substantially flush against a wall when disposed against the wall and coupled to the wall socket; and
a front housing coupled to the rear plate forming an enclosed volume adequate to house a plurality of electronic components.

2. The enclosure of claim 1, wherein the first aperture is rectangularly shaped.

3. The enclosure of claim 1, further comprising a third aperture extending through the rear plate, the third aperture sized to receive a fastener.

4. The enclosure of claim 1, wherein the front housing is releasably coupled to the rear plate.

5. The enclosure of claim 1, wherein the front housing is fixedly coupled to the rear plate.

6. The enclosure of claim 1, wherein the rear plate or the front housing is substantially square or rectangularly shaped.

7. The enclosure of claim 1, wherein the rear plate further comprises a plurality of standoffs extending therefrom, the plurality of standoffs forming a region for receiving and holding at least some of the plurality of electronic components.

8. The enclosure of claim 1, further comprising one or more tabs extending outward and away from the rear plate, the one or more tabs having an aperture extending therethrough that cooperates with an aperture on the front housing, the aperture in the one or more tabs sized to receive a fastener.

9. The enclosure of claim 8, wherein the front housing comprises a side wall with the aperture on the front housing extending therethrough and aligned with the aperture on the one or more tabs, and wherein the aperture on the front housing is sized to receive the fastener.

10. The enclosure of claim 1, further comprising one or more apertures extending through a side wall of the front housing, the one or more apertures sized and shaped to receive an Ethernet cable connector.

11. The enclosure of claim 1, further comprising a plurality of ventilation apertures passing through a sidewall of the front housing.

12. A security system, said system comprising:
a substantially planar rear plate, the rear plate having a wall with a first aperture and a second aperture extending therethrough, the first aperture shaped and sized to match a wall socket, and wherein the second aperture is sized to receive a fastener, and wherein the second aperture is disposed above or below the first aperture and positioned to line up with a fastener hole in the wall socket, and wherein the rear plate sits substantially flush against a wall when disposed against the wall and coupled to the wall socket;
a front housing coupled to the rear plate forming an enclosed volume adequate to house a plurality of electronic components; and
the plurality of electronic components disposed in the enclosed volume.

13. The system of claim 12, wherein the plurality of electronic components comprises a processor, an audible alarm, a memory card, or a modem.

14. The system of claim 12, further comprising one or more motion sensors or a smartlock wirelessly coupled with the plurality of electronics.

15. A method for mounting an enclosure for a security system to a wall, said method comprising:
providing an enclosure for a security system, the enclosure comprising a substantially planar rear plate and a front housing;
positioning the rear plate against the wall;
aligning an aperture in the rear plate with a wall socket such that the wall socket is accessible through the aperture;
coupling the rear plate to the wall socket with a fastener, wherein the rear plate rests substantially flush against the wall;
coupling one or more electronic components to the rear plate; and
attaching the front housing to the rear plate to form an enclosed volume that houses the one or more electronic components.

16. The method of claim 15, wherein the one or more electronic components comprise a power plug, the method further comprising passing the power plug through the aperture in the rear plate and plugging the power plug into the wall socket.

17. The method of claim 15, wherein coupling the rear plate to the wall socket comprises:
aligning an aperture in the rear plate with an aperture in the wall socket; passing a fastener through an aperture in the rear plate and into the aperture in the wall socket; and
threadably engaging the fastener with the wall socket.

18. The method of claim 15, wherein attaching the front housing to the rear plate comprises releasably attaching the front housing to the rear plate.

19. The method of claim 15, wherein attaching the front housing to the rear plate comprises fixedly attaching the front housing to the rear plate.

20. The method of claim 15, wherein attaching the front housing to the rear plate comprises passing a fastener through an aperture in the front housing and engaging the fastener with an aperture disposed in a tab extending outward and away from the rear plate.
